(19) United States
(12) Patent Application Publication
(10) Pub. No.: US 2026/0005048 A1
(43) Pub. Date: Jan. 1, 2026

(54) WAFER INDEXING MECHANISM FOR PROCESS MODULE

(71) Applicant: ASM IP Holding B.V., Almere (NL)

(72) Inventor: Salam Harb, Scottsdale, AZ (US)

(21) Appl. No.: 19/250,058

(22) Filed: Jun. 26, 2025

Related U.S. Application Data
(60) Provisional application No. 63/666,053, filed on Jun. 28, 2024.

(51) Int. Cl. H01L 21/67; H01L 21/677

(52) U.S. Cl. CPC H01L 21/67196; H01L 21/67259; H01L 21/67706

(57) ABSTRACT

A process module for a process module of a substrate processing system includes a vacuum chamber and a non-vacuum chamber. A substrate support is positioned in the vacuum chamber, is configured to support a substrate incoming into the vacuum chamber, and is coupled to a magnet. A metal component is further positioned to include a motor coil in the non-vacuum chamber. When the motor coil is energized, the motor coil and the magnet interact to generate a magnetic field allowing the substrate support to rotate about a first axis and place the substrate in a desired location. Rotary wafer indexers for process module of substrate processing systems and methods of making substrate indexers are also described.

### CROSS REFERENCE TO RELATED APPLICATIONS

The present application claims priority to the benefits of U.S. Provisional Patent Application No. 63/666,053, filed on Jun. 28, 2024, the contents of which is incorporated herein by reference in its entirety.

### FIELD OF INVENTION

The present disclosure generally relates to fabricating semiconductor devices, and more specifically, to substrate indexing in process modules during the fabrication of semiconductor devices.

### BACKGROUND OF THE DISCLOSURE

Conventional process manufacturers have capability to serve six independent process modules. In many conventional systems, four process chambers can be bundled into a single process module so that four wafers may be processed simultaneously in a single process module. However, to enable operation of four chambers into one process module, an indexing mechanism must be provided to accept wafers incoming from a vacuum robot in wafer handling chamber and rotate to place the wafers in a back chamber not proximate to the wafer handling chamber.

Generally, a wafer indexer is used inside the bundled process module for rotation motion of 180 degrees and linear motion along a Z-direction to pick and place the wafers into the desired susceptor. Conventionally, a servo motor is located in an ambient environment and the motor is coupled via a shaft and bearing that are hermetically sealed to the rotating arms inside the vacuum chamber. This rotating arm is capable of lifting and rotating four wafers simultaneously.

In conventional systems, ferrofluidic seals are used to hermetically seal process chambers from drive mechanism for rotary indexer. However, at elevated temperatures that process modules typical operate in, these seals may leak, outgas and contaminate chamber with oil substance used as carrier for the nanomagnetic particles that form the hermetical seal. Accordingly, there is a need for improvement in wafer indexing mechanism for process modules.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

A process module of a substrate processing system is provided. The process module includes a vacuum chamber, a magnet, a substrate support, and a motor coil. The magnet is disposed in the vacuum chamber. The substrate support is coupled to the magnet and is configured to support a substrate. The motor coil is disposed in a non-vacuum environment and, when energized, interacts with the magnet to rotate a substrate indexer about a first axis.

In addition to one or more of the features described above, or as an alternative, further examples of the process may include that the process module further includes a second metal component. The second metal component may separate the motor coil and the magnet from one another.

In addition to one or more of the features described above, or as an alternative, further examples of the process module may include that the second metal component includes a cylindrical section. The cylindrical section may have a top cylindrical side, a circumferential side and a cylindrical opening opposite the top cylindrical side that define an interior cylindrical section and an exterior cylindrical section. The interior cylindrical section of the cylindrical section of the second metal component may be exposed to the non-vacuum environment.

In addition to one or more of the features described above, or as an alternative, further examples of the process module may include that the motor coil is disposed in the interior cylindrical section alongside the circumferential side.

In addition to one or more of the features described above, or as an alternative, further examples of the process module may include that the magnet is disposed in the exterior cylindrical section alongside the circumferential side.

In addition to one or more of the features described above, or as an alternative, further examples of the process module may include that the second metal component includes a Z-shaped section. The Z-shaped section may include a top Z-side exposed to the vacuum chamber and a bottom Z-side exposed to the non-vacuum environment.

In addition to one or more of the features described above, or as an alternative, further examples of the process module may include that the cylindrical section is coupled to the Z-shaped section at the cylindrical opening.

In addition to one or more of the features described above, or as an alternative, further examples of the process module may include a first metal component. The first metal component may be coupled to the second metal component through an O-ring.

In addition to one or more of the features described above, or as an alternative, further examples of the process module may include that a first metal side of the first metal component is exposed to the vacuum chamber and a second metal side of the first metal component is exposed to the non-vacuum environment.

In addition to one or more of the features described above, or as an alternative, further examples of the process module may include that the substrate support includes a third metal component. The third metal component may be coupled to the second metal component. The third metal component may be disposed in the vacuum chamber. The third metal component may be configured to rotate about the first axis.

In addition to one or more of the features described above, or as an alternative, further examples of the process module may include that the magnet is coupled to the third metal component.

In addition to one or more of the features described above, or as an alternative, further examples of the process module may include that the third metal component is coupled to the second metal component through one or more bearings.

In addition to one or more of the features described above, or as an alternative, further examples of the process module may include that the one or more bearings and the magnet may be disposed on opposite sides of the third metal component.

In addition to one or more of the features described above, or as an alternative, further examples of the process module may include that the motor coil is energized by a source internal to the process module.

In addition to one or more of the features described above, or as an alternative, further examples of the process module may include that the first metal component is composed of at least one of aluminum, nickel, Hastelloy, Inconel, and titanium. The second metal component may be formed of at least one of aluminum, nickel, Hastelloy, Inconel, and titanium. The third metal component may be formed of at least one of aluminum, nickel, Hastelloy, Inconel, and titanium.

A wafer rotary indexer in a process chamber includes a magnet, a motor coil, and thin metal component. The magnet is disposed in a vacuum chamber. The motor coil is disposed in an atmospheric environment. The thin metal component hermetically separates the magnet and the motor such that a magnetic field generated by interaction between the magnet and the motor coil rotates a wafer rotary indexer about a first axis.

A method of making a substrate indexer for a process module of a substrate processing system is provided. The method includes disposing a substrate support configured to support one or more substrate in a vacuum chamber. The method also includes coupling a magnet to the substrate support, disposing a motor coil in a non-vacuum chamber, and separating the magnet and motor coil using a first metal component such that, when the motor is energized, the motor coil and the magnet interact to rotate the substrate support about first axis to a desired location.

In addition to one or more of the features described above, or as an alternative, further examples of the method may include that disposing the substrate support in the vacuum chamber further includes disposing a second metal component in the vacuum chamber and coupling the magnet with the second metal component.

In addition to one or more of the features described above, or as an alternative, further examples of the method may include coupling the first metal component with the second metal component using one or more bearings.

In addition to one or more of the features described above, or as an alternative, further examples of the method may include coupling a third metal component with the first metal component using an O-ring.

A wafer rotary indexer in a process chamber is provided. The indexer includes a magnet disposed in a vacuum chamber. The indexer further includes a motor coil disposed in an atmospheric environment. Finally, the indexer includes a thin metal component hermetically separating the magnet and the motor coil, such that the magnetic field generated by interaction between the magnet and the motor coil rotates a wafer rotary indexer about a first axis.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1A illustrates a top view of a substrate processing system in accordance with embodiments described herein;

FIG. 1B illustrates a top view of a process module included in the substrate processing system of FIG. 1A in accordance with embodiments described herein;

FIG. 2 illustrates a cross section view of a substate indexer in a process module of FIG. 1B in accordance with embodiments described herein;

FIG. 3 illustrates an exploded view of a metal component of substrate rotary indexer of FIG. 2 in accordance with embodiments described herein; and

FIG. 4 illustrates a flow diagram of a method a of forming a hermetical seal in a process module of a substrate processing system in FIG. 1 in accordance with embodiments described herein.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

Reference will now be made to the drawings wherein like reference numerals identify similar structural features or aspects of the subject disclosure. The systems and methods of the present disclosure may be in semiconductor processing systems employed to fabricate semiconductor devices, such as in semiconductor processing systems employed to deposit material layers using chemical vapor deposition (CVD) and atomic layer deposition (ALD) techniques during the fabrication of logic and memory devices, though the present disclosure is not limited to any specific semiconductor processing operation or to the fabrication of any particular type of semiconductor device in general.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers, for example in various shapes and sizes. Wafers may be 200 millimeters in diameter, 300 millimeters, or even 450 millimeters in diameter. Substrates may be formed from one or more semiconductor materials including by way of non-limiting example silicon, silicon germanium, silicon oxide, gallium arsenide, gallium nitride and silicon carbide.

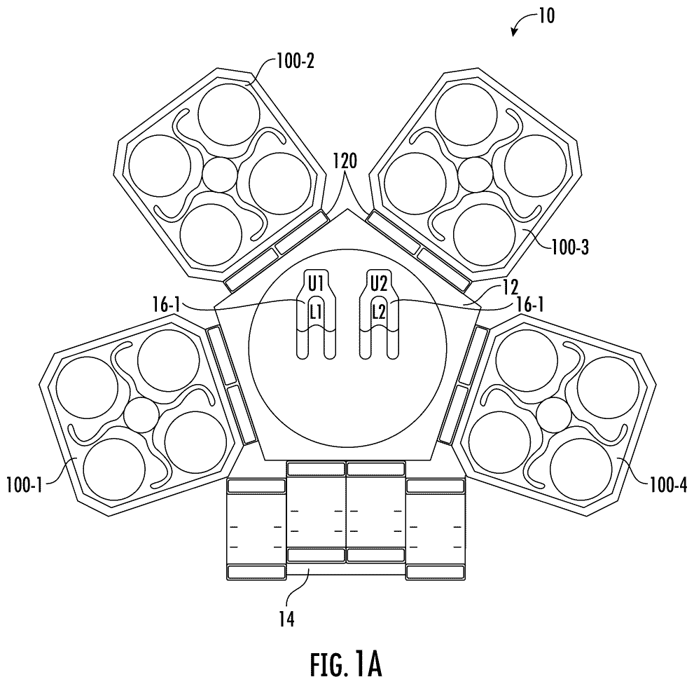

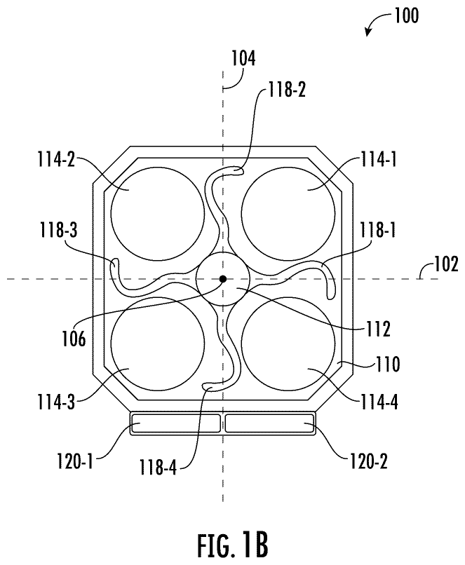

FIG. 1A illustrates a top view of a substrate processing system 10. Substrate processing system 10 includes an equipment front end module (EFEM), load lock module (LLM) 14, substrate handling chamber (SHC) 12, and one or more process module 100. Generally, unprocessed substrates are accessed by the substrate processing system at the EFEM for a pod, for example wafers delivered to the EFEM in a front-opening unified pod (FOUP). The EFEM includes a front end robot that is configured to obtain substrates from the pod and readied to be transported to the LLM 14. The transfer of substrates from LLM 14 to a process module is handled by one or more robots 16 in the SHC 12.

In exemplary embodiments, substrate processing system 10 may include a plurality of process modules, for example between four or six process modules 100, though substrate processing system 10 may include fewer or additional process modules 100. In the example shown in FIG. 1A, substrate processing system 10 includes four process modules (100-1, 100-2, 100-3, 100-4). Further, in exemplary embodiments, substrate processing system 10 may include a robot 16. Robot 16 may further include at least one arm with an end effector. The end effector is configured to support one or more substrate. Robot 16 accesses substrates from LLM 14 and places the substrate on to a substrate support (e.g., a susceptor 114) in process module 100. In the examples described herein, robot 16 includes two arms, each with an end effector so that two substrates can be transferred to a process module 100 simultaneously.

FIG. 1B illustrates a top view of an example process module 100 included in substrate processing system 10. Process module 100 includes at least one susceptor 114. In the example shown in FIG. 1B, process module 100 includes four susceptors 114-1, 114-2, 114-3 and 114-4. Process module 100 receives substrates from robot 16 in SHC via gate valve 120.

In the example shown in FIG. 1B, two gate valves 120-1 and 120-2 couple SHC (such as SHC 12) to process module 100. Accordingly, end effector(s) of robot 16 is able to move through gate valves 120-1 and 120-2 to transfer substrates from SHC 12 into process module 100 and place on susceptor 114. In the examples discussed herein, robot 16 can place substrates only on to the two susceptors closest to the gate valves 120-1 and 120-2. That is, because of limited motion of the end effector through the gate valves 120-1 and 120-2, end effector(s) of robot 16 is limited in placing substrates only on to susceptors 114-3 and 114-4 at one time.

To place substrates on susceptors 114-1 and 114-2 (that is, susceptor location non-proximate to gate valves 120-1 and 120-2), a rotation mechanism 112 is provided in process module 100. Process module 100 includes three axes: x-axis 102, y-axis 104 and z-axis 106. Process module 100 includes a substrate indexer 200 (e.g., a rotary wafer indexer including arms 118-1, 118-2, 118-3, and 118-4) having (e.g., configured for) rotation motion and linear motion. Rotation mechanism 112 allows substrate indexer 200 to rotate 180 degrees on the z-axis. In exemplary embodiments, substrate indexer 200 includes (e.g., is configured for) linear motion in the z-direction. Thus, a first set of two substrates can be placed on susceptors 114-3 and 114-4, the rotation mechanism 112 can be utilized to rotate the substrate indexer 200 by 180 degrees resulting in the susceptors 114-1 and 114-2 to be proximate to gate valves 120-1 and 120-2. Accordingly, after the 180-degree rotation, a second set of two substrates can be placed on susceptors 114-1 and 114-2 before starting the deposition process. Thus, all four susceptors in 114-1, 114-2, 114-3 and 114-4 in process module 100 are occupied by substrates for simultaneous processing.

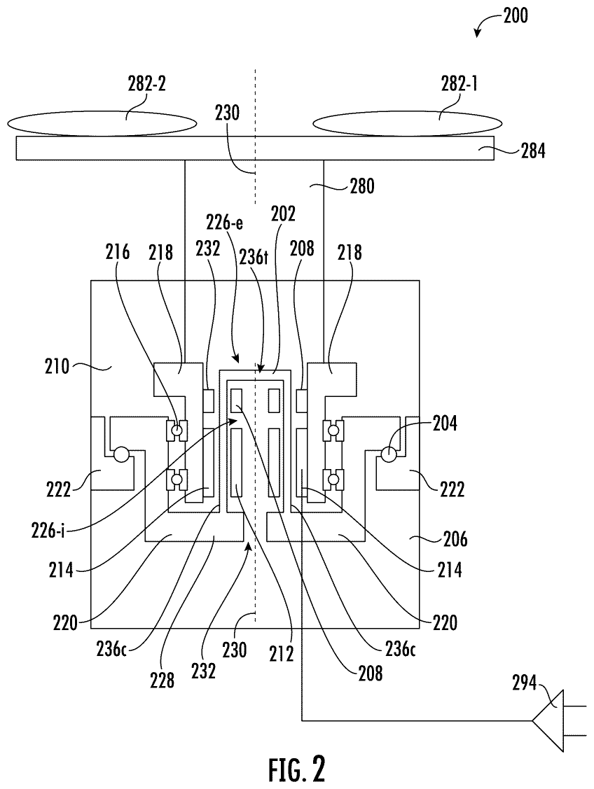

Rotation motion of the substrate indexer 200 is accomplished using a motor coil 212 in one environment and a magnet 214 in a second environment separated by a hermetical seal. FIG. 2 illustrates a cross section view of an example substrate indexer 200 in a process module 100. Substrate indexer 200 is configured to rotate substrates (such as substrates 282-1 and 282-2, which may be wafers) around axis 230. Substrate indexer 200 is included in a first environment 206 and a second environment 210. That is, the first environment 206 and second environment 210 have different pressure ambient. For example, first environment 206 can be a high pressure ambient and second environment 210 may be a low pressure ambient, or vice versa. In exemplary embodiments, the first environment 206 is atmospheric (ATM pressure) environment. In exemplary embodiments, the second environment 210 is a vacuum chamber.

Further, the first environment 206 and second environment 210 are separated by a metallic section. In exemplary embodiments, metallic section includes a plurality of metal components. As shown in FIG. 2, a first metal component 222 is coupled to a second metal component 220. The first metal component 222 is positioned about axis 230. In exemplary embodiment, the first metal component 222 is coupled to the second metal component 220 via an O-ring 204. In exemplary embodiments, the first metal component 222 is stationary. Further, as shown in FIG. 2, in exemplary embodiments, first metal component 222 is an L-shaped piece positioned in a radial fashion about axis 230 (e.g., the cross section of first metal component 222 may resemble the letter “L” and be described an ‘L-shaped”).

In exemplary embodiments, second metal component 220 includes a Z-shaped section 228 (e.g., the cross section of the Z-shaped section 228 may resemble the letter “Z” and be described as “Z-shaped”) and a substantially cylindrical section 202. The second metal component 220 is positioned in a radial fashion about axis 230. In exemplary embodiments, the second metal component 220 is stationary. In certain examples the second metal component 220 may hermetically separate the motor coil 212 and the magnet 214. In this respect it is contemplated that the second metal component 220 may include a cylindrical section 202 having a top cylindrical side 236t, a circumferential side 236c and a cylindrical opening 232 axially opposite the top cylindrical side 236t that define an interior cylindrical section 226i and an exterior cylindrical section 226e. In such examples the interior cylindrical section 226i may be exposed to the non-vacuum environment

Cylindrical section 202 includes circumferential side 236c, top cylindrical side 236t and a cylindrical opening 232 instead of a bottom side to complete the cylindrical section 202. The cylindrical section 202 may be formed about axis 230. Cylindrical section 202 includes an interior cylindrical section 226i and an exterior cylindrical section 226e. Cylindrical opening 232 in the cylindrical section 202 is formed such that the interior cylindrical section 226i of the cylindrical section 202 is exposed to the first environment 206. As shown in FIG. 2, cylindrical opening 232 is coupled to (e.g., bounded by) the Z-shaped section 228. Cylindrical section 202 protrudes into the second environment 210 such that top cylindrical side 236t and the circumferential side 236c are exposed to second environment 210 on the exterior cylindrical section 226e.

Cylindrical section 202 forms a bulkhead composed of thin-metal material. In exemplary embodiments the thin-metal material may be a non-magnetic material. In further exemplary embodiments, the thin-metal material may be composed of one of a corrosion-resistant and/or oxidation-resistant metal such as aluminum, nickel, Hastelloy, Inconel, or titanium. In exemplary embodiments, the thin-metal material forming the cylindrical section 202 is thinner than the width of the Z-shaped section 228 of the second metal component 220, first metal component 222 and the third metal component 218. In exemplary embodiments, two or more of the cylindrical section 202, the first metal component 222, the second metal component 220, and the third metal component 218 may have the same (e.g., substantially equivalent) dimensions or wall thicknesses.

Further, in exemplary embodiments, substrate indexer 200 further includes a third metal component 218. Third metal component 218 is coupled to the Z-shaped section 228 of the second metal component 220. In exemplary embodiments, third metal component 218 is coupled to the Z-shaped section 228 of the second metal component 220 by utilizing one or more bearings 216. In exemplary embodiments, third metal component 218 is a reverse (e.g., inverted relative to gravity) L-shaped piece. In the example shown in FIG. 2, third metal component 218 is completely located in the second environment 210. That is, third metal component 188 is exposed only to the second environment 210 but not to first environment 206. As further shown in FIG. 2, a magnet 214 is directly coupled to the third metal component 218.

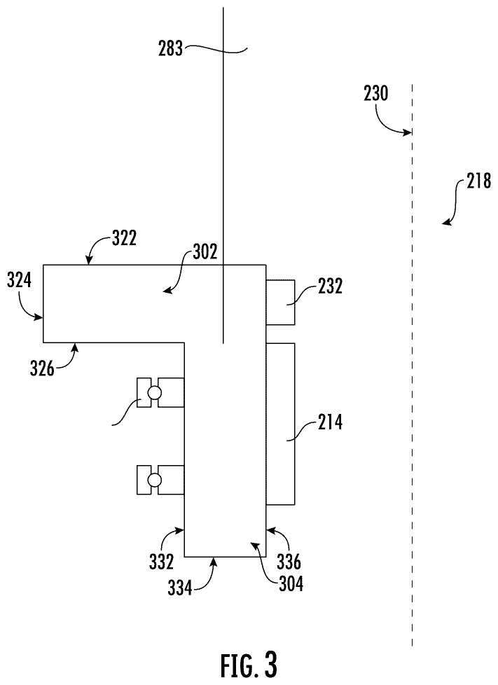

Turning briefly to FIG. 3, FIG. 3 shows an exploded view of third metal component 218 of substrate indexer 200. As shown in FIG. 3, third metal component 218 includes a wider section 302 and a longer section 304 that are perpendicular. Further, third metal component 218 includes a top side 322, a first wide side 324, a second wide side 326, a first long side 332, a bottom side 334, and a second long side 336. The top side 322, second wide side 326 and bottom side 334 are parallel. Further, first wide side 324, first long side 332 and second long side 336 are parallel. As further seen in FIG. 3, one or more bearing 216 is coupled to first long side 332 and magnet 214 is coupled to second long side 336.

Turning back to FIG. 2, substrate indexer 200 further includes a motor coil 212. Motor coil 212 is disposed in first environment 206. In exemplary embodiments, motor coil 212 is disposed in the interior cylindrical section 226i. In further exemplary embodiments, motor coil 212 is disposed alongside circumferential side 236c. As further shown in FIG. 2, magnet 214 is also disposed alongside circumferential side 236c but in the exterior cylindrical section 226e (e.g., an exterior cylindrical section). Accordingly, motor coil 212 is disposed alongside circumferential side 236c in first environment 206 and magnet 214 is disposed alongside circumferential side 236c in second environment 210.

As further seen in FIG. 2, motor coil 212 is coupled to a source 294. Motor coil 212 can be energized by controlling an electric current provided by source 294. Source 294 may be internal or external to substrate indexer 200. When motor coil 212 is energized, motor coil 212 interacts with magnet 214 (through the hermetical seal while separated by cylindrical section 202) via a magnetic field generated by electric current flowing through the motor coil 212. This magnetic field allows rotational motion of third metal component 218 around axis 230.

Thus, wider section 302 of third metal component 218 functions as a rotation axis. As further shown in FIG. 2, wider section 302 of third metal component 218 is connected to a rotational support 280. Rotational support 280 is further connected to a rotation pedestal 284, and rotation pedestal 284 is configured to support substrates 282. Rotational support 280 and rotation pedestal 284 are both positioned about axis 230 in a radial manner. Thus, when third metal component 218 rotates about axis 230, rotational support 280 and rotation pedestal 284 also rotate in the same direction as third metal component 218. Accordingly, substrates 282 may be supported by rotation pedestal 284 and rotation pedestal 284 are also rotated.

As described previously, the energy generated by the motor coil 212 (i.e. current provided to motor coil 212) may be adjusted by source 294. By controlling the current provided to the motor coil, rotation of the third metal component 218 (and consequently the substrate indexer 200) may be adjusted to a desired amount.

In exemplary embodiments, when a substrate 282 is received in process module 100 (for example, from SHC 12), rotation pedestal 284 may support substrate(s) 282. Motor coil 212 may then be energized resulting in rotation of the substrate support (e.g., the third metal component 218, rotational support 280 and rotation pedestal 284 supporting substrate(s) 282). After the desired amount of rotation is achieved (for example, when the substrate reaches the location of the desired susceptor), current provided to the motor coil 212 is adjusted to stop the rotation. Substrate 282 may then be placed in the location of the desired susceptor.

Thus, by controlling the energy generated by the motor coil (e.g., a current provided to the motor coil), substrate indexer 200 may be rotated to a desired amount. In the example shown in FIG. 2 because magnet 214 is in a low pressure (for example, vacuum) environment it is protected from atmospheric contamination (such as, hydrogen). In exemplary embodiments, substrate indexer 200 further includes a printed circuit board (PCB) 208 that is coupled alongside circumferential side 236c. In exemplary embodiments, first metal component, second metal component and third metal component are composed of the same metallic material. In exemplary embodiments, they are composed of different material.

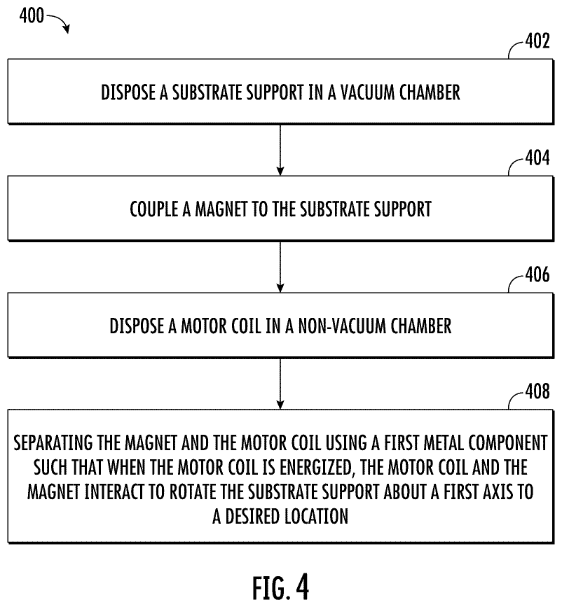

FIG. 4 illustrates a method 400 of making of a substrate indexer for a process module of a substrate processing system. Method 400 includes disposing a substrate support in a vacuum chamber, such as vacuum chamber 210, as shown with box 402. Method 400 further includes coupling a magnet, such as magnet 214, to the substrate support, as shown with box 404. In exemplary embodiments of method 400, disposing the magnet in a vacuum chamber further includes disposing a second metal component, such as third metal component 218, in the vacuum chamber and coupling the magnet with the second metal component.

Method 400 further includes disposing a motor coil, such as motor coil 212, in a non-vacuum chamber, such as an atmospheric environment, as shown with box 406. Method 400 further includes separating the magnet and the motor coil using a first metal component, such as second metal component 220, such that when the motor coil is energized, the motor coil and the magnet interact to rotate the substrate support about the first axis, such as axis 230, to a desired location, as shown with box 408.

In exemplary embodiments, method 400 further includes coupling the first metal component with the second metal component using one or more bearings, such as bearings 216. In exemplary embodiments, method 400 further comprises coupling a third metal component, such as first metal component 222, with the first metal component using an O-ring, such as O-ring 204.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A process module of a substrate processing system comprises:
a vacuum chamber;
a magnet disposed in the vacuum chamber;
a substrate support coupled to the magnet and configured to support a substrate; and
a motor coil disposed in a non-vacuum environment,
wherein when the motor coil is energized, the motor coil and the magnet interact to rotate a wafer indexer about a first axis.

2. The process module of claim 1, further comprising a second metal component hermetically separating the motor coil and the magnet.

3. The process module of claim 2, wherein the second metal component comprises a cylindrical section having a top cylindrical side, a circumferential side and a cylindrical opening opposite the top cylindrical side that define an interior cylindrical section and an exterior cylindrical section; and wherein the interior cylindrical section is exposed to the non-vacuum environment.

4. The process module of claim 3, wherein the motor coil is disposed in the interior cylindrical section alongside the circumferential side.

5. The process module of claim 4, wherein the magnet is disposed in the exterior cylindrical section alongside the circumferential side.

6. The process module of claim 3, wherein the second metal component comprises a Z-shaped section, wherein the Z-shaped section comprises a top Z-side exposed to the vacuum chamber and a bottom Z-side exposed to the non-vacuum environment.

7. The process module of claim 6, wherein the cylindrical section is coupled to the Z-shaped section at the cylindrical opening.

8. The process module of claim 2, further comprising a first metal component coupled to the second metal component through an O-ring.

9. The process module of claim 8, wherein a first metal side of the first metal component is exposed to the vacuum chamber and a second metal side of the first metal component is exposed to the non-vacuum environment.

10. The process module of claim 2, wherein the substrate support comprises a third metal component coupled to the second metal component, wherein the third metal component is disposed in the vacuum chamber, and wherein the third metal component is configured to rotate about the first axis.

11. The process module of claim 10, wherein the magnet is coupled to the third metal component.

12. The process module of claim 11, wherein the third metal component is coupled to the second metal component through one or more bearings.

13. The process module of claim 12, wherein the one or more bearings and the magnet are disposed on opposite sides of the third metal component.

14. The process module of claim 1, wherein the motor coil is energized by a source internal to the process module.

15. The process module of claim 2, wherein the second metal component is composed of at least one of aluminum, nickel, Hastelloy, Inconel, and titanium.

16. A rotary wafer indexer for a process chamber of a substrate processing system, comprising:
a magnet disposed in a vacuum chamber;
a motor coil disposed in an atmospheric environment; and
a thin metal component hermetically separating the magnet and the motor coil, such that a magnetic field generated by interaction between the magnet and the motor coil rotates a wafer rotary indexer about a first axis.

17. A method of making of a substrate indexer for a process module of a substrate processing system, the method comprising:
disposing a substrate support in a vacuum chamber, the substrate support configured to support one or more substrates;
coupling a magnet to the substrate support;
disposing a motor coil in a non-vacuum chamber; and
separating the magnet and the motor coil using a second metal component such that when the motor coil is energized, the motor coil and the magnet interact to rotate the substrate support about a first axis to a desired location.

18. The method of claim 17, wherein disposing the substrate support in a vacuum chamber further comprises:
disposing a third metal component in the vacuum chamber; and
coupling the magnet with the third metal component.

19. The method of claim 18, further comprising coupling the third metal component with the second metal component using one or more bearings.

20. The method of claim 17, further comprising coupling a first metal component with the second metal component using an O-ring.
